(19) United States
(12) Patent Application Publication
(10) Pub. No.: US 2020/0203520 A1
(43) Pub. Date: Jun. 25, 2020

(54) GALLIUM NITRIDE DEVICES INCLUDING A TUNNEL BARRIER LAYER

(71) Applicant: Texas Instruments Incorporated, Dallas, TX (US)

(72) Inventors: Nicholas S. DELLAS, Dallas, TX (US); Qhalid Fareed Rangoon Sayeed, Plano, TX (US)

(21) Appl. No.: 16/228,364

(22) Filed: Dec. 20, 2018

(51) Int. Cl. H01L 29/778; H01L 29/66; H01L 21/02

(52) U.S. Cl. CPC H01L 29/7787; H01L 21/02381; H01L 21/0254; H01L 29/66462

(57) ABSTRACT

In some examples, a gallium-based device comprises a substrate layer; a first group-III nitride layer supported by the substrate layer; a second group-III nitride layer supported by the first group-III nitride layer; a tunnel barrier layer supported by the second group-III nitride layer; a passivation layer supported by the tunnel barrier layer; and source, gate, and drain contact structures supported by the first group-III nitride layer.

### SUMMARY

In accordance with one example, a gallium-based device comprises a substrate layer; a first group-III nitride layer supported by the substrate layer; a second group-III nitride layer supported by the first group-III nitride layer; a tunnel barrier layer supported by the second group-III nitride layer; a passivation layer supported by the tunnel barrier layer; and source, gate, and drain contact structures supported by the first group-III nitride layer.

In accordance with another example, a method of fabricating a gallium-based device comprises obtaining a substrate; growing a first group-III nitride layer that is supported by the substrate; growing a second group-III nitride layer that is supported by the first group-III nitride layer; growing a tunnel barrier layer that is supported by the second group-III nitride layer; growing a passivation layer that is supported by the tunnel barrier layer; and depositing source, gate, and drain contact structures that are supported by the second group-III nitride layer.

In accordance with yet another example, a gallium-based transistor comprises a substrate including silicon; a seed layer positioned on the silicon substrate; a gallium nitride layer positioned on the seed layer; an aluminum gallium nitride layer positioned on the gallium nitride layer, wherein a two-dimensional electron gas (2DEG) is at an interface of the aluminum gallium nitride layer and the gallium nitride layer; an aluminum nitride layer positioned on the aluminum gallium nitride layer; a passivation layer positioned on the aluminum nitride layer; and source, drain, and gate contact structures supported by the aluminum gallium nitride layer.

### BRIEF DESCRIPTION OF THE DRAWINGS

For a detailed description of various examples, reference will now be made to the accompanying drawings in which:

FIG. 1 depicts a cross-section of an illustrative gallium nitride (GaN)-based transistor, in accordance with various examples.

FIG. 2 depicts an illustrative modified design assembly of a GaN-based device, in accordance with various examples.

FIG. 3 depicts an illustrative method to fabricate a GaN-based transistor with a modified design assembly, in accordance with various examples.

FIGS. 4(a)-4(g) are illustrative flow diagrams depicting at least some of the steps involved in fabricating a gallium nitride (GaN)-based transistor with a modified design assembly.

### DETAILED DESCRIPTION

Gallium nitride (GaN)-based devices are designed to include heterostructures that induce a two dimensional electron gas (2DEG) in such devices. These heterostructures typically include at least two group-III nitride-based layers with different bandgaps. In this disclosure, group-III is referred to the third group of elements from the widely known periodic table. In some cases, the heterostructure may include a first group-III nitride layer that, along with nitride, includes two or more group-III elements. For example, the first group-III nitride layer may include aluminum and gallium as the group-III elements and has a chemical composition of Al(X)Ga(1-X)N, where X is the concentration of aluminum. The heterostructure includes a second group-III nitride layer, which is grown on the first group-III nitride layer. An example of the second group-III nitride layer includes at least GaN. In this heterostructure, the first group-III nitride layer has a broader bandgap relative to the second group-III nitride layer. Due to the bandgap mismatch and large conduction-band offset, the heterostructure produces spontaneous and/or piezoelectric polarization and induces the highly-mobile 2DEG at their interface.

For the sake of illustration, some of the description herein focuses on GaN-based devices, such as GaN-based transistors. However, the disclosure is not limited to transistors and can be applied to other GaN-based devices that include heterostructures. Again, for the sake of illustration, some of the description herein focuses on heterostructures including the first and second group-III nitride layers. However, this disclosure is not limited to such heterostructures and can be applied to other heterostructures that can induce a 2DEG at their interface.

GaN-based transistors can be classified as enhancement mode high electron mobility transistors (e-HEMTs) or depletion mode high electron mobility transistors (d-HEMTs). A gate contact structure is generally positioned between the source and drain contact structures of GaN-based transistors. The architecture of these gate contact structures assists in forming the enhancement and depletion mode devices. Some e-HEMT architecture includes p-doped GaN gate contact structure (or p-GaN gate contact structure), which depletes electrons from the 2DEG under the p-GaN gate contact structure. This incomplete 2DEG makes e-HEMTs normally-OFF devices. e-HEMTs can be turned ON by applying a positive threshold voltage to the gate contact structure that attracts electrons from the GaN layer and repletes the 2DEG under the gate contact structure turning the e-HEMT ON. On the other hand, d-HEMTs are designed to be normally-ON devices, meaning that the 2DEG is always present between the source and drain contact structures. D-HEMTs are turned OFF by applying a negative threshold voltage to the gate contact structure that depletes electrons from the 2DEG under the gate contact structure.

Compared to silicon-based transistors, GaN-based transistors deliver superior switching characteristics. However, GaN-based transistors suffer from current collapse, which is an undesirable phenomenon that occurs under switching conditions, e.g., when the GaN-based transistor is turned on and off at a high voltage. Current collapse is believed to be caused by electron trapping and de-trapping, which appears as a transient and recoverable reduction in the drain current after the application of a high voltage. For the sake of illustration, assume an e-HEMT including Al(X)Ga(1-X)N layer (or “AlGaN layer”), where X is the concentration of aluminum and GaN layer. Further assume that the e-HEMT is in off-state and has the following voltage states: a drain voltage of 600V, a gate voltage below the threshold, and a grounded source voltage. Under this off-state condition, injection of high-energy electrons takes place from the 2DEG towards the surface of the AlGaN layer, or at the interface of the AlGaN layer and a passivation layer that is typically deposited on the AlGaN layer. Due to electron injection, near surface traps and surface states (that are formed due to high voltage switching) are filled, reducing 2DEG density and expanding the depletion width which results in an increased on-resistance (Ron). This causes current collapse because during the on-state condition, e.g., at a drain voltage of 600V, gate voltage above the threshold, and a grounded source voltage, the electrons in these states are emitted, leading to recovery transients. In other words, during the on-state, the Ron reduces over time (e.g., a few microseconds), thereby increasing the drain current over time. Thus, systems and methods are needed to mitigate the issue of current collapse, which occurs due to trapping/de-trapping of electrons at the surface of the AlGaN layer, or at the interface of the AlGaN layer and the passivation layer.

Accordingly, at least one of the systems disclosed herein is directed towards HEMTs (both e-mode and d-mode) that implement a modified design assembly. The modified design assembly is configured to substantially prevent the tunneling of the electrons from the 2DEG to the surface traps and states, thereby substantially preventing current collapse.

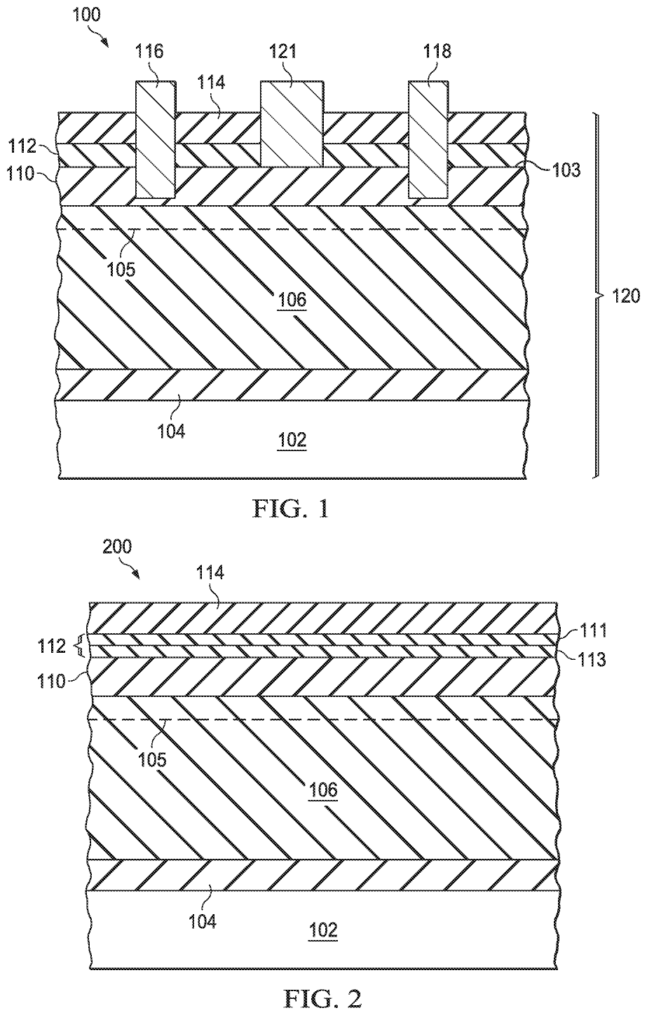

Referring now to FIG. 1, a cross-section of an illustrative GaN-based transistor 100 (hereinafter transistor 100) with the modified design assembly 120 is shown. The transistor 100 depicted in FIG. 1 is a depletion mode GaN-based transistor. The transistor 100 is fabricated on a substrate layer (or “substrate”) 102, which can include silicon, silicon carbide, sapphire, gallium nitride-based substrate or other suitable substrate material. In examples where silicon based substrate is employed, the transistor 100 needs to position a seed layer 104 on the substrate 102 as, in such examples, the seed layer 104 is necessary for the subsequent growth of the layers in the modified design assembly 120. In examples where a gallium-based substrate is employed, the use of the seed layer 104 may be avoided. The example shown in FIG. 1 assumes that the substrate 102 is silicon-based. In some examples, the seed layer 104 has a thickness of 0.1-0.5 microns and includes aluminum nitride (AlN). In other examples, other suitable material that can facilitate the growth of the subsequent layers of the modified design assembly 120 may be used as the seed layer 104.

The transistor 100 further includes multiple group-III nitride layers, such as a first group-III nitride layer 106 and a second group-III nitride layer 110. The first group-III nitride layer 106 differs from the second group-III nitride layer 110 in that their chemical composition is different. The second group-III nitride layer 110 includes, along with nitride, two or more group-III elements, e.g., aluminum (Al), indium (In), and gallium (Ga). The second group-III nitride layer 110 can be, at least partially, derived from a general form of Al(X)In(Y)Ga(1-X-Y)N, where X and Y are the concentrations of Al and In, respectively. On the other hand, the first group-III nitride layer 106, along with nitride, includes one group-III element, e.g., gallium. At least a portion of the first group-III nitride layer 106 has a chemical composition of Ga(1)N.

For simplicity's sake, the second group-III nitride layer 110 is hereinafter referred to as AlGaN layer 110 and the first group-III nitride layer 106 is hereinafter referred to as GaN layer 106.

The GaN layer 106 is supported by the substrate 102 and the AlGaN layer 110 is supported by the GaN layer 106. The term “support” or “supported by” used in this disclosure is intended to mean either an indirect or direct support. Thus, if GaN layer 106 is supported by the substrate 102, that support may be through a direct support with the substrate 102 or through an indirect support via other layers. In some examples, an aluminum nitride (AlN) (not expressly shown in FIG. 1) layer is deposited between the GaN and AlGaN layers 106, 110, respectively. This AlN layer is disposed in order to strain the subsequently grown AlGaN layer to increase electron mobility and, in some examples, the AlN layer has a thickness of 10 angstrom.

In some examples, the GaN layer 106 may have a graded chemical composition, meaning that a portion of the GaN layer 106 may have a concentration of elements that is different from the concentration of elements of another portion of the GaN layer 106. For example, a first portion (not shown) of the GaN layer 106 may have the chemical composition of Al(0.5)Ga(0.5)N and a second portion (not shown) may have a chemical composition of Al(0.3)Ga(0.7)N. The thickness of the first and second compositions can be in the range of 0.2 um to 2 um. The GaN layer 106 also includes a third portion (not shown) that has the chemical composition of Ga(1)N. This third portion may be doped with carbon, or some other suitable dopant, or may have some unintentional doping. The thickness of the third portion, in some examples, can be in the range of 2-3 um. In some examples, the GaN layer 106 excluded the first and second portion, and, in such examples, the third portion largely forms the GaN layer 106. On the other hand, in some examples, the AlGaN layer 110 may have a non-graded chemical composition, such that a composition of, for instance, Al(0.3)Ga(0.7)N uniformly forms the AlGaN layer 110. In other examples, AlGaN layer 110 may have a graded chemical composition of Aluminum, Gallium, and Indium. For example, different compositions, such as Al(0.2)Ga(0.8)N; Al(0.1)Ga(0.9)N may form the AlGaN layer 110.

AlGaN layer 110 has a top side 103. FIG. 1 also depicts a 2DEG 105 that is formed at the interface of the GaN layer 106 and the AlGaN layer 110. As noted above, 2DEG 105 is enabled by the large conduction band offset of the GaN layer 106 and the AlGaN layer 110. Although the description herein assumes that the transistor 100 includes a heterostructure comprising AlGaN layer 110 and GaN layer 106 that forms the 2DEG 105 at their interface, however, this disclosure also applies to other transistors that include a heterostructure that induces a 2DEG in it.

The transistor 100 further includes a tunnel barrier layer 112 that is supported by the AlGaN layer 110 and is configured to substantially prevent the electrons from the 2DEG 105 to transport to the surface traps and states by introducing a wide-bandgap that acts as a tunneling-barrier for the electrons. The surface states and traps may exist at the interface of passivation layer 114 and the tunnel barrier layer 112. Stated another way, the presence of the tunnel barrier layer 112 prevents electron injection from the 2DEG 105 to the surface states and this further prevents the current collapse phenomenon.

The tunnel barrier layer 112 is grown between the passivation layer 114 and the AlGaN layer. The passivation layer 114 is supported by the tunnel barrier layer 112. In order to prevent the electrons to transport to the surface states/traps, the tunnel barrier layer 112 has a bandgap higher than the bandgap of the AlGaN layer 110. The thickness of the tunnel barrier layer 112 is critical because if the thickness of the tunnel barrier layer 112 is above a threshold thickness, it will result in the formation of a parasitic 2DEG channel at the interface of the AlGaN layer 110 and the tunnel barrier layer 112. In some examples, the threshold thickness of the tunnel barrier layer 112 is 10 nm.

In some examples, the tunnel barrier layer 112 can assume a chemical composition of Al(X1)In(Y1)Ga(Z1)N, where X1, Y1, and Z1 are respective concentrations of aluminum, indium, and gallium. For example, a composition of Al(0.79)Ga(0.21)N forms the tunnel barrier layer 112. In some examples, the tunnel barrier layer 112 includes aluminum nitride (AlN), meaning the concentration of gallium and indium is zero, which makes the tunnel barrier layer 112 aluminum-rich. The tunnel barrier 112 including AlN is more thermally stable and reduces the density of surface states, which is advantageous.

In other examples, the tunnel barrier layer 112 may assume a graded chemical composition of Al(X1)In(Y1)Ga(Z1)N. In another example, the tunnel barrier layer 112 may be oxidized to form AlO(X1)N(Y1) (where AlO is aluminum oxide) to further increase the energy height of the tunnel barrier. Briefly referring to FIG. 2, which depicts an illustrative modified design assembly 200. The modified design assembly is similar to the modified design assembly 120 except for the tunnel barrier layer 112. The tunnel barrier layer 112 of FIG. 2 depicts a graded composition. For example, the tunnel barrier layer 112 of FIG. 2 shows layers 111, 113 which are of different compositions, such as Al(0.8)Ga(0.2)N; Al(0.9)Ga(0.1)N, respectively. It is advantageous to have an aluminum-rich (e.g., aluminum concentration greater than 0.5 relative to gallium concentration) tunnel barrier layer 112. In other examples, the passivation layer 114 can include silicon dioxide, silicon nitride, or other suitable dielectric layers.

Referring back to FIG. 1, the transistor 100 further includes a source contact structure 116, a gate contact structure 121, and a drain contact structure 118. The source contact structure 116, the gate contact structure 121, and the drain contact structure 118 are supported by the AlGaN layer 110. The term “support” or “supported by” is intended to mean either an indirect or direct support. Thus, if drain contact structure 118 and source contact structure 116 are supported by the AlGaN layer 110, that support may be through a direct support with the AlGaN layer 110 or through an indirect support via other layers. Accordingly, the contact structures 116, 121, 118 can also be said to be supported by the GaN layer 106. The term “direct support” may mean disposed on or partially disposed inside the supporting layer. In one example, the source contact structure 116 forms an ohmic contact with the AlGaN layer 110. The ohmic contact Is a low resistance junction that provides current conduction between the source contact structure 116 and the AlGaN layer 110.

As noted above, the example transistor 100 depicted in FIG. 1 is a depletion mode transistor. Therefore, the gate contact structure 121 is disposed on the top side 103 and forms, in one example, an ohmic contact with the AlGaN layer 110. However, if the transistor 100 were to function in an enhancement mode, the transistor 100 may include a p-doped GaN layer that is positioned between the top side 103 and the gate contact structure 121. The p-doped GaN layer enables such transistors to function in the enhancement mode as the presence of the p-doped GaN layer depletes the electrons present in the 2DEG 105 under the p-doped GaN layer. The gate contact structure 121 forms, in one example, an ohmic contact with the pGaN layer (not depicted). In other examples, a Schottky contact can be formed between the two. In some examples, the source contact structure 116, the gate contact structure 121, and the drain contact structure 118 may include a bilayer of titanium and aluminum capped with titanium nitride.

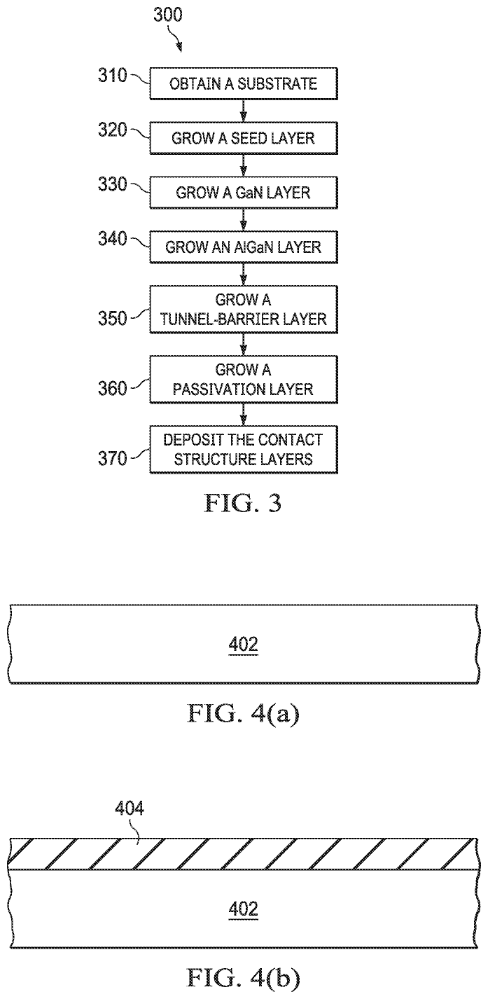

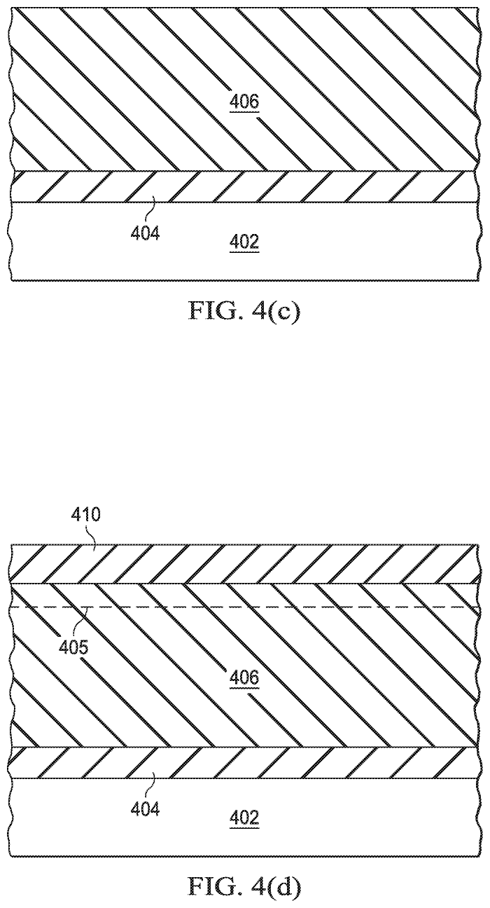

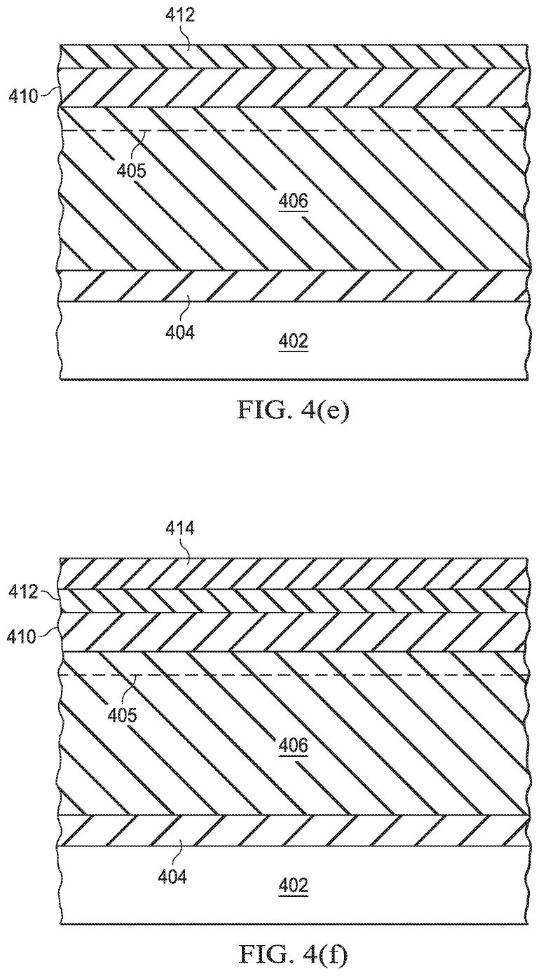

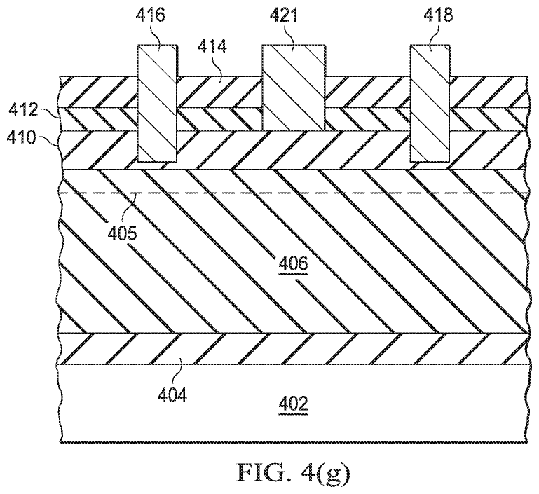

Referring now to FIG. 3, an illustrative method 300 to fabricate a depletion mode transistor (e.g., transistor 100) with a modified design assembly (e.g., modified design assembly 120) is shown. FIGS. 4(a)-4(g) are illustrative flow diagrams depicting at least some of the steps involved in fabricating the transistor with the modified design assembly. The method 300 is now described in tandem with FIGS. 4(a)-FIG. 4(g).

In some examples, the method 300 is performed in a chemical vapor deposition (CVD) growth chamber, e.g., metal organic chemical vapor deposition (MOCVD) growth chamber. The CVD growth chamber (not expressly shown) includes a source gas supply system (not expressly shown) for supplying a source gas, a susceptor (not expressly shown) for supporting a substrate 402 (FIG. 4(a)), and an evacuation unit (not expressly shown), such as a vacuum pump for evacuating gases that have causes a reaction. The growth chamber is controlled to have a desired internal pressure of, e.g., 50-100 Torr, and based on the chemical composition of the layer to be grown, one or more of the metal organic sources such as TMG (trimethyl gallium), TMA (trimethyl aluminum), TMI (trimethyl indium), and the like, are introduced into the growth chamber. These gaseous sources are transported to the growth chamber by a hydrogen carrier gas, where the hydrogen carrier gas is generally used after removing impurities by passing through a purifier (not shown). The flow rate of these source gases can be controlled by a mass flow controller (not shown).

The method 300 beings with a step 310 that includes obtaining the substrate 402 and loading it into the growth chamber (FIG. 4(a)). For illustration's sake, it is assumed that the substrate 402 includes silicon. Following the step 310, the method 300 proceeds to a step 320 that includes growing a seed layer 404 (FIG. 4(b)). As noted above, the seed layer 404 is needed to grow the subsequent layers in an example where the substrate 402 includes silicon. In this example, the seed layer 404 includes AlN and is grown by introducing TMA in a nitrogen rich gas chamber at 1000-1050° C. for a desired time, which may at least depend on the desired thickness of the AlN layer.

Following growing the seed layer 404, the method 300 proceeds to step 330 that includes growing a GaN layer 406 (FIG. 4(c)). In one example, the GaN layer 406 can be grown to have a chemical composition of Al(0)Ga(1)N, which can be intentionally or unintentionally doped. In such examples, the flow rate of TMA is brought down to zero and GaN forms due to the continuous flow of TMG. In other examples, the GaN layer 406 can be grown additively where the concentration of the aluminum is reduced and the concentration of gallium is increased over time. In such examples, the flow rate of TMA is reduced and the flow rate of TMG is increased. In such examples, the GaN layer 406 can be said to have a non-uniform chemical composition, meaning that a portion of the GaN layer 406 has a graded composition, e.g., Al(0.6)Ga(0.4)N; Al(0.45)Ga(0.55)N; Al(0.2)Ga(0.8)N; and Al(0)Ga(1)N, where the concentration of aluminum gradually reduces and the concentration of gallium gradually increases. In such examples, after achieving Al(0)Ga(1)N concentration, the rest of the GaN layer 406 can be grown such that it has uniform GaN concentration. In some examples, after achieving Al(0)Ga(1)N concentration, the rest of the GaN layer 406 can be doped by flowing a dopant gas (e.g., carbon gas) in the growth chamber. In some examples, due to contaminants present in the growth chamber, the GaN layer 406 can be unintentionally doped by unwanted dopants.

Following growing the GaN layer 406, the method 300 proceeds to a step 340 that includes growing an AlGaN layer 340 (FIG. 4(d)). In some examples, this is done by controlling the flow rate of TMA and TMG such that the AlGaN layer 340 has a substantially uniform chemical composition, for example, Al(0.26)Ga(0.74)N. FIG. 4(d) also depicts a 2DEG formed at the interface of GaN layer 406 and AlGaN layer 410. Following the step 340, the method 300 moves to a step 350 that includes growing a tunnel barrier layer 412 (FIG. 4(e)) on the AlGaN layer 410. In some examples, the tunnel barrier layer 412 layer has a chemical composition of Al(1)Ga(0)N. This chemical composition is achieved by stopping the flow of TMG in the growth chamber and flowing TMA such that the tunnel barrier layer 340 has a substantially uniform chemical composition of Al(1)Ga(0)N. In other examples, the tunnel barrier layer 412 can be grown additively where the concentration of the aluminum is increased relative to the aluminum concentration of the AlGaN layer 410 and the concentration of gallium is reduced relative to the gallium concentration of the AlGaN layer 410. In such examples, the flow rate of TMA is increased and the flow rate of TMG is decreased. In such examples, the tunnel barrier layer 412 has a graded composition, e.g., Al(0.22)Ga(0.8)N; Al(0.45)Ga(0.55)N; and Al(0.9)Ga(0.1)N, where the concentration of aluminum gradually increases and the concentration of gallium gradually decreases.

Following growing the AlN layer, the method 300 moves to a step 360 that includes growing a passivation layer 360 (FIG. 4(f)). The passivation layer may be grown by low pressure chemical vapor deposition (LPCVD), atomic layer deposition (ALD), plasma enhanced chemical vapor deposition (PECVD), or other thin film deposition techniques. Following step 360, the method 300 proceeds to step 370 that includes depositing, using for instance a metal-deposition process (sputter, evaporation, etc.), the drain contact structure 418, the gate contact structure 421, and the source contact structure 416 (FIG. 4(g)). FIG. 4(g) depicts the contact structures 416 and 418 partially disposed in the AlGaN layer 410, whereas the gate contact layer 421 is positioned on the AlGaN layer 410. This can be achieved by first forming a mask layer that may be a dry film or a photoresist film covered on the top of the passivation layer 414 through a suitable coating process, which may be followed by curing, descum, and the like, further followed by lithography technology and/or etching processes, such as a dry etch and/or a wet etch process to form etched portions which extend from the top side of the passivation layer 414 into the AlGaN layer 410 for the contact structures 416, 418, whereas an etched position which extends from the top side of the passivation layer 414 to the top side of the AlGaN layer 410. Following forming the etched portions, the contact structures 416, 418, 421 are deposited.

In the foregoing discussion and in the claims, the terms “including” and “comprising” are used in an open-ended fashion, and thus should be interpreted to mean “including, but not limited to . . . .” “X” Also, the term “support” or “supported by” used in this disclosure is intended to mean either an indirect or direct support. Thus, if one layer is supported by another layer, that support may be through a direct support with the supporting layer or through an indirect support via other layers. An element or feature that is “configured to” perform a task or function may be configured (e.g., programmed or structurally designed) at a time of manufacturing by a manufacturer to perform the function and/or may be configurable (or re-configurable) by a user after manufacturing to perform the function and/or other additional or alternative functions. The configuring may be through firmware and/or software programming of the device, through a construction and/or layout of hardware components and interconnections of the device, or a combination thereof. Additionally, uses of the phrases “ground” or similar in the foregoing discussion are intended to include a chassis ground, an Earth ground, a floating ground, a virtual ground, a digital ground, a common ground, and/or any other form of ground connection applicable to, or suitable for, the teachings of the present disclosure. Unless otherwise stated, “about,” “approximately,” or “substantially” preceding a value means+1-10 percent of the stated value.

The above discussion is meant to be illustrative of the principles and various embodiments of the present disclosure. Numerous variations and modifications will become apparent to those skilled in the art once the above disclosure is fully appreciated. It is intended that the following claims be interpreted to embrace all such variations and modifications.

What is claimed is:

1. A gallium-based device, comprising:
a substrate layer;
a first group-III nitride layer supported by the substrate layer;
a second group-III nitride layer supported by the first group-III nitride layer;
a tunnel barrier layer supported by the second group-III nitride layer;
a passivation layer supported by the tunnel barrier layer; and
source, gate, and drain contact structures supported by the first group-III nitride layer.

2. The gallium-based device of claim 1, wherein the substrate layer includes silicon.

3. The gallium-based device of claim 2, wherein a seed layer is positioned between the substrate layer and the first group-III nitride layer.

4. The gallium-based device of claim 1, wherein at least a portion of the first group-III nitride layer has a chemical composition of Al(0)Ga(1)N.

5. The gallium-based device of claim 1, wherein the second group-III nitride layer has a chemical composition of Al(X)In(Y)Ga(1-X-Y)N, wherein X and Y are concentrations of aluminum (Al) and Indium (In), respectively, and 1-X-Y is the concentration of gallium (Ga).

6. The gallium-based device of claim 1, wherein the tunnel barrier layer includes aluminum nitride (AlN).

7. The gallium-based device of claim 1, wherein the tunnel barrier layer has a chemical composition of Al(X)In(Y)Ga(1-X-Y)N, wherein X and Y are concentrations of aluminum and Indium, respectively, and 1-X-Y is the concentration of gallium (Ga).

8. A method of fabricating a gallium-based device, comprising:
obtaining a substrate;
growing a first group-III nitride layer that is supported by the substrate;
growing a second group-III nitride layer that is supported by the first group-III nitride layer;
growing a tunnel barrier layer that is supported by the second group-III nitride layer;
growing a passivation layer that is supported by the tunnel barrier layer; and
depositing source, gate, and drain contact structures that are supported by the second group-III nitride layer.

9. The method of claim 8, wherein the substrate includes silicon.

10. The method of claim 8, wherein the at least a portion of the first group-III nitride layer has a chemical composition of Al(0)Ga(1)N.

11. The method of claim 8, wherein the second group-III nitride layer has a chemical composition of Al(X)In(Y)Ga(1-X-Y)N, where X, Y are concentrations of aluminum and Indium, respectively, and 1-X-Y is the concentration of gallium (Ga).

12. The method of claim 8, wherein the tunnel barrier layer includes aluminum nitride (AlN).

13. The method of claim 8, wherein the tunnel barrier layer has a chemical composition of Al(X)In(Y)Ga(1-X-Y)N, where X, Y are concentrations of aluminum and Indium, respectively, and 1-X-Y is the concentration of gallium (Ga).

14. A gallium-based transistor, comprising:
a substrate including silicon;
a seed layer positioned on the silicon substrate;
a gallium nitride layer positioned on the seed layer;
an aluminum gallium nitride layer positioned on the gallium nitride layer, wherein a two-dimensional electron gas (2DEG) is at an interface of the aluminum gallium nitride layer and the gallium nitride layer;
an aluminum nitride layer positioned on the aluminum gallium nitride layer;
a passivation layer positioned on the aluminum nitride layer; and
source, drain, and gate contact structures supported by the aluminum gallium nitride layer.

15. The gallium-based transistor of claim 14, wherein the aluminum nitride layer is configured to prevent electrons from the 2DEG to tunnel to the passivation layer.

16. The gallium-based transistor of claim 14, wherein the seed layer includes aluminum nitride.

17. The gallium-based transistor of claim 14, wherein at least a portion of the gallium nitride layer has a chemical composition of Al(0)Ga(1)N.

18. The gallium-based transistor of claim 14, wherein at least another portion of the gallium nitride layer has a chemical composition of Al(X)In(Y)Ga(1-X-Y)N, where X, Y are the concentrations of aluminum and indium, respectively, and 1-X-Y is the concentration of gallium (Ga).

19. The gallium-based transistor of claim 14, wherein the aluminum gallium nitride layer has a chemical composition of Al(X)In(Y)Ga(1-X-Y)N, where X, Y are concentrations of aluminum and Indium, respectively, and 1-X-Y is the concentration of gallium (Ga).

20. The gallium-based transistor of claim 14, wherein the passivation layer includes silicon dioxide.
